(19) United States
(12) Patent Application Publication
(10) Pub. No.: US 2014/0062579 A1
(43) Pub. Date: Mar. 6, 2014

(54) APPARATUS FOR FLUID CONTROL DEVICE MONITORING

(71) Applicants: Bruce Rigsby, Charlestown, IN (US); Michael Simmons, Louisville, KY (US); Jennifer A. Floyd, Louisville, KY (US); Robert L. LaFountain, Charlestown, IN (US); Bruce Penning, Louisville, KY (US)

(72) Inventors: Bruce Rigsby, Charlestown, IN (US); Michael Simmons, Louisville, KY (US); Jennifer A. Floyd, Louisville, KY (US); Robert L. LaFountain, Charlestown, IN (US); Bruce Penning, Louisville, KY (US)

(21) Appl. No.: 13/598,242

(22) Filed: Aug. 29, 2012

(51) Int. Cl. H03K 17/945

(52) U.S. Cl. 327/517

(57) ABSTRACT

Apparatus for fluid control device monitoring are disclosed. An example apparatus includes a body through which a shaft extends. The shaft is to be coupled to an actuator. An angular position of the shaft is based on a position of the actuator. The apparatus includes a target coupled to the shaft and a circuit including a user configurable switch and a proximity switch. The user configurable switch is configurable to a first state or a second state. When the user configurable switch is in the first state and the target is distant from the proximity switch, the circuit is to output a first signal. When the user configurable switch is in the second state and the target is distant from the proximity switch, the circuit is to output a second signal different than the first signal.

### FIELD OF THE DISCLOSURE

This patent relates generally to fluid control devices and, more particularly, to apparatus for fluid control device monitoring.

### BACKGROUND

Sensors may be used to determine an actual valve position. Based on the sensor reading, the sensor outputs a value, which may be used to control the position of the valve.

### SUMMARY

An example apparatus in accordance with the teachings of this disclosure includes a body through which a shaft extends. The shaft is to be coupled to an actuator. An angular position of the shaft is based on a position of the actuator. The apparatus includes a target coupled to the shaft and a circuit including a user configurable switch and a proximity switch. The user configurable switch is configurable to a first state or a second state. When the user configurable switch is in the first state and the target is distant from the proximity switch, the circuit is to output a first signal. When the user configurable switch is in the second state and the target is distant from the proximity switch, the circuit is to output a second signal different than the first signal.

Another example apparatus in accordance with the teachings of this disclosure includes a resistor and first and second switches. The resistor is in parallel with the first and second switches. The first switch is in series with the second switch. The first switch is responsive to a target and the second switch is responsive to user input. An output of the apparatus is to change based on the user input when the target is proximate the first switch or when the target is at a distance from the first switch.

### BRIEF DESCRIPTION OF THE DRAWINGS

FIG. 1 depicts an example apparatus to monitor a fluid control device.

FIG. 2 depicts an example circuit that can be used to implement the example apparatus of FIG. 1.

### DETAILED DESCRIPTION

Certain examples are shown in the above-identified figures and described in detail below. In describing these examples, like or identical reference numbers are used to identify the same or similar elements. The figures are not necessarily to scale and certain features and certain views of the figures may be shown exaggerated in scale or in schematic for clarity and/or conciseness. Additionally, several examples have been described throughout this specification. Any features from any example may be included with, a replacement for, or otherwise combined with other features from other examples.

The examples disclosed herein relate to configurable Namur interface circuitry and/or valve top monitoring systems for fluid control device monitoring. Depending on the configuration of the example circuitry, a current output increases or decreases if a target is present. Thus, a single apparatus may be used in applications having different electrical requirements while outputting standard Namur switch current levels when the target is or is not present. In some examples, the interface circuitry provides Namur output with Exna certification such that an additional intrinsically safe barrier is not needed.

In some examples, the Namur circuitry includes a field-effect transistor (FET), first and second resistors, a user configurable switch and a proximity sensor (e.g., a mechanical proximity switch). To provide a different result (e.g., high or low current output) based on the same proximity sensor reading, the user configurable switch is responsive to user settings. For example, with the user configurable switch in a first state and/or setting and the proximity sensor in the normally closed position, the output current may be at a first and/or higher value (e.g., 3 milliamps and/or greater than 3 milliamps). However, if the user configurable switch is in a second state and/or setting when the proximity switch is in the normally closed position, the output current may be at a second and/or lower value (e.g., 1 milliamp and/or less than 3 milliamps).

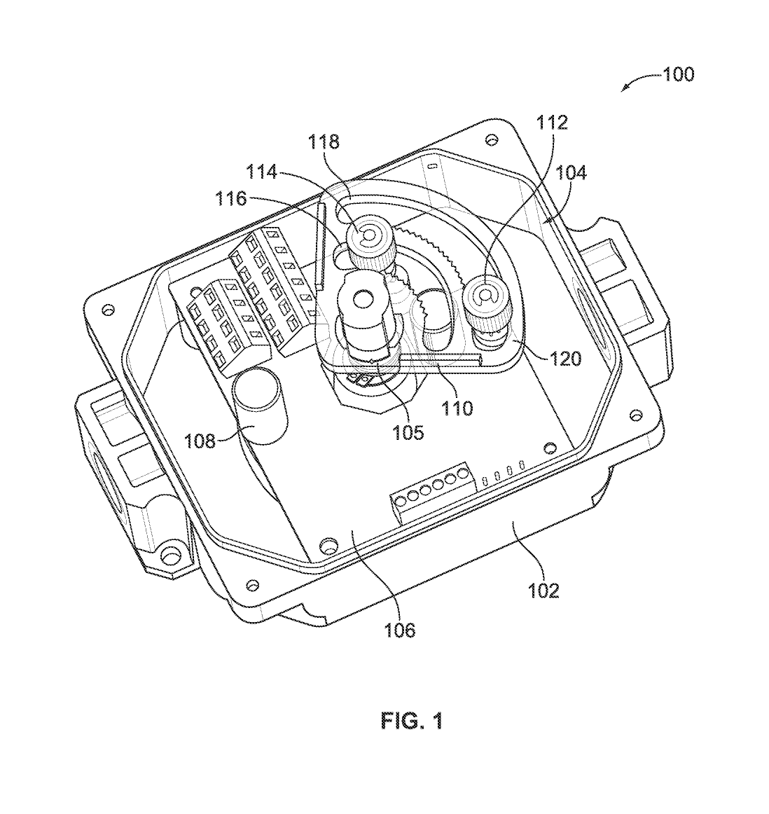

FIG. 1 depicts an example apparatus 100 one or more of which are used to monitor a position of a fluid control device. The apparatus 100 includes a housing 102 in which a position monitor (e.g., a valve position monitor) 104 is mounted. The position monitor 104 includes a shaft 105 that extends through the housing 102 and a circuit (e.g., a constant current circuit) 106 mounted within the housing 102. A switch 108 and a switch and/or sensor 110 are coupled to the circuit 106. In other examples, instead of the circuit 106 being external to the switch 108 and/or the switch 110, the circuit 106 may be integral to the switch 108 and/or the switch 110.

The switch 108 may be a user configurable switch (e.g., a dip switch) that is responsive to user input and the switch 110 may be a proximity sensor or a switch responsive to one or more targets 112, 114. The targets 112, 114 may be metal, magnets, ferromagnetic material, etc. In some examples, the switch 108, the switch 110 and/or the housing 102 are hermetically sealable to enable the apparatus 100 to be used in hazardous and/or underwater locations. In some examples, the housing 102 and/or other components of the apparatus 100 may be made and/or molded using high-temperature resistant materials (e.g., plastics) to enable the apparatus 100 to be used in high-temperature environments. In some examples, the housing 102 may include one or more internal and/or external light-emitting diodes (e.g., LEDs) to indicate the state of the switch 108 and/or the switch 110.

In operation, the circuit 106 receives an input voltage of between about 8 and 30 volts direct current and the shaft 105, which is coupled to an actuator, changes its rotational and/or angular position based on the position of the actuator. The positions of the targets 112, 114 relative to the switch 110 change based on the position of the shaft 105. The targets 112, 114 are movably coupled within respective slots (e.g., serrated slots) 116, 118 of a follower and/or segmented plate 120 coupled to the shaft 105. Based on the position of the target 114 relative to the switch 110, the current output of the circuit 106 changes.

In some examples, if the target 114 is detected by the switch 110 and the switch 108 is in a first state, the circuit 106 is not shorted and the current output is relatively low. In some examples, if the target 114 is detected by the switch 110 and the switch 108 is in a second state, the circuit 106 is shorted and the current output is relatively high. Thus, the example apparatus 100 can be used in different applications having electrical configurations that expect the amperage to be higher or lower when the target 114 is present.

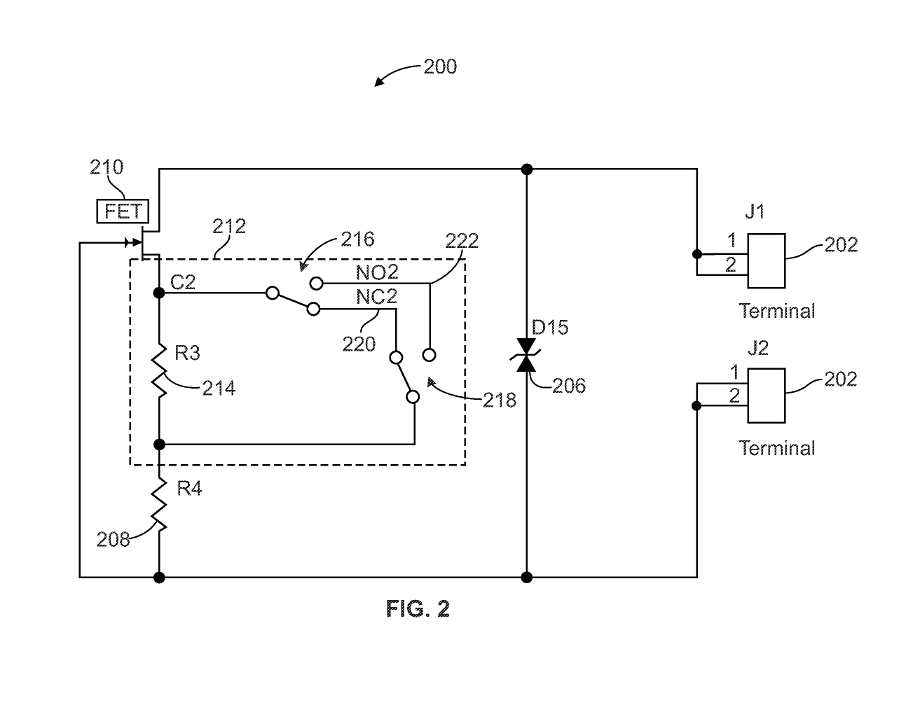

FIG. 2 depicts an example circuit 200 in accordance with the teachings of this disclosure. The circuit 200 includes terminals 202, 204, a transient voltage protector 206 such as a bidirectional diode, a first resistor 208, a FET 210 and a current control circuit 212. In some examples, the current control circuit 212 includes a second resistor 214 and first and second switches 216, 218. In this example, the first resistor 208 is coupled in series with the second resistor 214 and/or the first and second switches 216, 218 and the first and second switches 216, 218 are coupled in series. In some examples, the first switch 216 is a user configurable dip switch and/or a single pole, double throw switch and is responsive to user input and the second switch 218 is a proximity sensor or switch responsive to a target (e.g., the target 114).

In operation, depending on the expected output, the second switch 218 may be in a first state and/or coupled to a normally closed segment (NC2) 220 or in a second state and/or coupled to a normally open segment (NO2) 222. When the first and second switches 216 and 218 are coupled to the normally closed segment 220 (e.g., in a first state), as shown in FIG. 2, the second resistor 214 is shorted and the effective voltage to a gate and source of the FET 210 is increased. The increase in voltage to the FET 210 increases current flow through the FET 210 (e.g., a first current value and/or output). When the first switch 216 is coupled to the normally closed segment 220 (e.g., a first state) and the second switch 218 is coupled to the normally open segment 222 (e.g., the target is present, a second state), the second resistor 214 is not shorted and the effective voltage to the gate and source of the FET 210 is decreased. The decrease in voltage to the FET 210 decreases current flow through the FET 210 (e.g., a second current value and/or output).

When the first switch 216 is coupled to the normally open segment 222 and the second switch 218 is coupled to the normally closed segment 220, the second resistor 214 is not shorted and the output current is decreased. When the first switch 216 and the second switch 216 are coupled to the normally open segment 222, the second resistor 214 is shorted and the output current is increased.

As set forth herein, an example apparatus includes a body through which a shaft extends. The shaft is to be coupled to an actuator. An angular position of the shaft is based on a position of the actuator. The apparatus includes a target coupled to the shaft and a circuit includes a user configurable switch and a proximity switch. The user configurable switch is configurable to a first state or a second state. When the user configurable switch is in the first state and the target is distant from the proximity switch, the circuit is to output a first signal. When the user configurable switch is in the second state and the target is distant from the proximity switch, the circuit is to output a second signal different than the first signal.

In some examples, the user configurable switch is in the first state and the target is proximate the proximity switch, the circuit is to output the second signal. In some examples, when the user configurable switch is in the second state and the target is proximate the proximity switch, the circuit is to output the first signal. In some examples, the user configurable switch includes a single pole, double throw switch or a dip switch. In some examples, the first signal has a magnitude greater than the second signal. In some examples, when the user configurable switch is in the first state and the target is distant from the proximity switch, a resistor of the circuit is shorted. In some examples, when the user configurable switch is in the second state and the target is proximate the proximity switch, a resistor of the circuit is shorted.

Another example apparatus includes a body through which a shaft extends. The shaft is to be coupled to an actuator and a target is coupled to the shaft. The apparatus includes a proximity sensor responsive to the target and means for obtaining different outputs when the target is proximate the proximity sensor or when the target is at a distance from the proximity senor. In some examples, the means for obtaining different outputs includes a user configurable switch configurable to a first state or a second state. In some examples, when the user configurable switch is in the first state and the target is at the distance from the proximity sensor, a circuit is to output a first current value. In some examples, when the user configurable sensor is in the second state and the target is distant from the proximity sensor, the circuit to output a second current value different than the first current value.

In some examples, when the user configurable switch is in the first state and the target is proximate the proximity sensor, the circuit is to output the second current value. In some examples, when the user configurable switch is in the second state and the target is proximate the proximity sensor, the circuit is to output the first current value. In some examples, when the user configurable switch is in the first state and the target is at the distance from the proximity sensor, a resistor of the circuit is shorted.

Another example apparatus includes a resistor and first and second switches. The resistor is in parallel with the first and second switches. The first switch is in series with the second switch. The first switch is responsive to a target and the second switch is responsive to user input. An output of the apparatus is to change based on the user input when the target is proximate the first switch or when the target is at a distance from the first switch.

In some examples, the apparatus also includes a second resistor in series with the first resistor and the first and second switches. In some examples, the first switch includes a proximity sensor. In some examples, the second switch includes a single pole, double throw switch. In some examples, an input voltage of the apparatus is to be between about 8 volts and 30 volts. In some examples, when the second switch is in a first state and the target is at the distance from the first switch, the output is to be a first current value. In some examples, when the second switch is in a second state and the target is at the distance from the first switch, the output is to be a second current value different than the first current value. In some examples, the first current value has a magnitude greater than the second current value.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. An apparatus, comprising:
a body through which a shaft extends, the shaft to be coupled to an actuator, an angular position of the shaft based on a position of the actuator;
a target coupled to the shaft; and
a circuit comprising a user configurable switch and a proximity switch, the user configurable switch configurable to a first state or a second state, wherein when the user configurable switch is in the first state and the target is distant from the proximity switch, the circuit to output a first signal, wherein when the user configurable switch is in the second state and the target is distant from the proximity switch, the circuit to output a second signal different than the first signal.

2. The apparatus of claim 1, wherein when the user configurable switch is in the first state and the target is proximate the proximity switch, the circuit to output the second signal.

3. The apparatus of claim 1, wherein when the user configurable switch is in the second state and the target is proximate the proximity switch, the circuit to output the first signal.

4. The apparatus of claim 1, wherein the user configurable switch comprises a single pole, double throw switch or a dip switch.

5. The apparatus of claim 1, wherein the first signal has a magnitude greater than the second signal.

6. The apparatus of claim 1, wherein when the user configurable switch is in the first state and the target is distant from the proximity switch, a resistor of the circuit is shorted.

7. The apparatus of claim 1, wherein when the user configurable switch is in the second state and the target is proximate the proximity switch, a resistor of the circuit is shorted.

8. An apparatus, comprising:
a body through which a shaft extends, the shaft to be coupled to an actuator;
a target coupled to the shaft;
a proximity sensor responsive to the target; and
means for obtaining different outputs when the target is proximate the proximity sensor or when the target is at a distance from the proximity senor.

9. The apparatus of claim 8, wherein the means for obtaining different outputs comprises a user configurable switch configurable to a first state or a second state.

10. The apparatus of claim 9, wherein when the user configurable switch is in the first state and the target is at the distance from the proximity sensor, a circuit is to output a first current value, wherein when the user configurable sensor is in the second state and the target is distant from the proximity sensor, the circuit to output a second current value different than the first current value.

11. The apparatus of claim 10, wherein when the user configurable switch is in the first state and the target is proximate the proximity sensor, the circuit to output the second current value.

12. The apparatus of claim 10, wherein when the user configurable switch is in the second state and the target is proximate the proximity sensor, the circuit to output the first current value.

13. The apparatus of claim 10, wherein when the user configurable switch is in the first state and the target is at the distance from the proximity sensor, a resistor of the circuit is shorted.

14. An apparatus, comprising:
a resistor; and
first and second switches, the resistor in parallel with the first and second switches, the first switch in series with the second switch, the first switch responsive to a target and the second switch responsive to user input, wherein an output of the apparatus is to change based on the user input when the target is proximate the first switch or when the target is at a distance from the first switch.

15. The apparatus of claim 14, further comprising a second resistor in series with the first resistor and the first and second switches.

16. The apparatus of claim 14, wherein the first switch comprises a proximity sensor.

17. The apparatus of claim 14, wherein the second switch comprises a single pole, double throw switch.

18. The apparatus of claim 14, wherein an input voltage of the apparatus is to be between about 8 volts and 30 volts.

19. The apparatus of claim 14, wherein when the second switch is in a first state and the target is at the distance from the first switch, the output to be a first current value, wherein when the second switch is in a second state and the target is at the distance from the first switch, the output to be a second current value different than the first current value.

20. The apparatus of claim 19, wherein the first current value has a magnitude greater than the second current value.
